(19) United States
(12) Patent Application Publication
(10) Pub. No.: US 2010/0244195 A1
(43) Pub. Date: Sep. 30, 2010

(54) HOST SUBSTRATE FOR NITRIDE BASED LIGHT EMITTING DEVICES

(75) Inventors: Limin Lin, New Territories (HK); Bin Xie, New Territories (HK); Shu Yuan, New Territories (HK)

Correspondence Address: BROOKS KUSHMAN P.C., 1000 TOWN CENTER, TWENTY-SECOND FLOOR, SOUTHFIELD, MI, 48075, US

(73) Assignee: HONG KONG APPLIED SCIENCE AND TECHNOLOGY RESEARCH INSTITUTE CO. LTD., New Territories (HK)

(21) Appl. No.: 12/412,702

(22) Filed: Mar. 27, 2009

(51) Int. Cl. H01L 29/20; H01L 21/302

(52) U.S. Cl. 257/615; 438/458; 438/460; 438/694; 257/E29.089; 257/E21.214

(57) ABSTRACT

A host substrate and method of making a host substrate for nitride based thin-film semiconductor devices are provided. According to one embodiment, the method includes the steps of providing a silicon layer; etching a pattern of holes in the silicon layer; plating the silicon layer with copper to fill the holes etched in the silicon layer; bonding the silicon layer to a gallium nitride (GaN) layer, the GaN layer attached to a sapphire substrate; and removing the sapphire substrate. The host substrate is configured to address the coefficient of thermal expansion (CTE) mismatch problem and reduce the amount of stress resulting from such CTE mismatch. A combination of metal and semiconductor materials provide for the desired thermal and electrical conductivity while providing for subsequent dicing and incorporation of the finished semiconductor devices into other circuits.

### FIELD OF THE INVENTION

The present invention relates to semiconductor devices, and more particularly, to a host substrate for nitride-based light emitting devices.

### BACKGROUND OF THE INVENTION

Light emitting diodes (LEDs) is currently one of the most innovative and fastest growing technologies in the semiconductor industry. While LEDs have been in use for decades as indicators and for signaling purposes, technology developments and improvements have allowed for a broader use of LEDs in illumination applications.

Semiconductors that contain nitrogen (N) as the Group V element have proven to be useful for short-wavelength light emitting devices. Among these, extensive research has been conducted on gallium-nitride based semiconductors for use as light emitting diodes, such as InₓGa1-ₓN and AlₓGa_{y}In_{z}N, and such LED have already been put to practical use.

Generally, GaN-based LEDs are grown on a sapphire substrate. The GaN semiconductor layers are grown on a sapphire substrate. But sapphire is not a good thermal or electrical conductor, so a host substrate is attached to the GaN semiconductor layers and the sapphire is removed. The host substrate must satisfy many requirements, such as providing sufficient mechanical support, providing good thermal and electrical conductivity, and CTE (coefficient of thermal expansion) matching. CTE mismatch can result in large amounts of stress, which results in cracks in the GaN layers and reliability problems.

Presently known materials for substrate substitution have a number of limitations. For example, a pure metal such as Cu, while providing thermal and electrical conductivity, has a large CTE mismatch, is soft and not easy to use in a device fabrication process, and is difficult to be diced using either laser or dicing saws with a cutting street width of less than 100 um. SU8 can be used to separate the copper substrate before plating, but this process increases costs and process difficulty. Moreover, it can be hard to incorporate such devices into integrated circuits based on silicon. With metal alloys, such as copper tungsten (CuW), while providing better CTE matching, a high volume of tungsten is required, which can degrade the performance of copper. With a pure semiconductor material, such as silicon, it is cheap and easy to integrate devices into circuits. However, a pure semiconductor material provides much less thermal and electrical conductivity than copper and limits the device performance when scaling up the size of the LEDs.

Accordingly, there is a need for an LED substrate that addresses these and other shortcomings of known substrate materials.

### SUMMARY OF THE INVENTION

According to one embodiment of the present invention, a method of making a host substrate for nitride based thin-film semiconductor devices is disclosed. The method includes the steps of providing a semiconductor layer; etching a pattern of holes in the semiconductor layer; plating the semiconductor layer with metal to fill the holes etched in the semiconductor layer; bonding the semiconductor layer to a gallium nitride (GaN) layer, the GaN layer attached to a sapphire substrate; and removing the sapphire substrate.

According to another embodiment of the present invention, a method of making a host substrate for nitride based thin-film semiconductor devices is disclosed. The method includes the steps of providing a silicon layer; etching a pattern of blind holes in a side of the silicon layer; bonding the silicon layer to a gallium nitride (GaN) layer, the GaN layer attached to a sapphire substrate, wherein the side of the silicon layer having the pattern of holes is bonded to the GaN layer; thinning the silicon layer to expose the pattern of holes in the silicon layer; plating the silicon layer with copper to fill the holes etched in the silicon layer; and removing the sapphire substrate.

According to another embodiment of the present invention, a nitride based semiconductor structure having a host substrate is disclosed. The nitride-based semiconductor includes a sapphire substrate; and one or more semiconductor layers formed on the substrate, wherein one of the one or more semiconductor layers includes a plurality of metal sections, wherein the silicon layer defines a plurality of holes patterned in the silicon layer, and the plurality of metal sections include metal filled in the plurality of holes.

According to another embodiment of the present invention, a nitride based semiconductor structure having a host substrate is disclosed. The nitride-based semiconductor includes a sapphire substrate; one or more gallium nitride (GaN) layers formed on the sapphire substrate; a metal layer plated to the one or more GaN layers; and a semiconductor layer bonded to the metal layer.

According to another embodiment of the present invention, a nitride based semiconductor structure having a host substrate is disclosed. The nitride-based semiconductor includes a sapphire substrate; and one or more gallium nitride (GaN) layers formed on the sapphire substrate; a metal layer plated to the one or more GaN layers, wherein the metal layer includes a combination of two different metals.

Still other embodiments of the present invention will become readily apparent to those skilled in the art from the following detailed description, wherein embodiments of the invention are described by way of illustration. As will be realized, the invention is capable of other and different embodiments and its several details are capable of modifications in various respects, all without departing from the spirit and the scope of the present invention.

### BRIEF DESCRIPTION OF THE DRAWINGS

FIG. 1 is a partial cross sectional view of a semiconductor structure, in accordance with an embodiment of the present invention.

FIG. 2 is a partial cross sectional view of a semiconductor structure, in accordance with an embodiment of the present invention.

FIG. 3 is a partial cross sectional view of a semiconductor structure, in accordance with an embodiment of the present invention.

FIG. 4 is a partial cross sectional view of a semiconductor structure, in accordance with an embodiment of the present invention.

FIG. 5 is a partial cross sectional view of a semiconductor structure, in accordance with an embodiment of the present invention.

FIG. 6 is a partial cross sectional view of a semiconductor structure, in accordance with an embodiment of the present invention.

FIG. 7 is a partial cross sectional view of a semiconductor structure, in accordance with an embodiment of the present invention.

FIG. 8 is a partial cross sectional view of a semiconductor structure, in accordance with an embodiment of the present invention.

FIG. 9 is a partial cross sectional view of a semiconductor structure, in accordance with an embodiment of the present invention.

FIG. 10 is a partial cross sectional view of a semiconductor structure, in accordance with an embodiment of the present invention.

FIG. 11 is a partial cross sectional view of a semiconductor structure, in accordance with an embodiment of the present invention.

FIG. 12 is a partial cross sectional view of the semiconductor structure shown in FIG. 11, with the sapphire substrate removed, in accordance with an embodiment of the present invention.

FIG. 13 is a plan view of the semiconductor structure shown in FIGS. 6 and 11, in accordance with an embodiment of the present invention.

FIG. 14 is a partial cross sectional view of a semiconductor structure, in accordance with an embodiment of the present invention.

FIG. 15 is a partial cross sectional view of the semiconductor structure shown in FIG. 14, with the sapphire substrate removed, in accordance with an embodiment of the present invention.

FIG. 16 is a partial cross sectional view of a semiconductor structure, in accordance with an embodiment of the present invention.

FIG. 17 is a partial cross sectional view of the semiconductor structure shown in FIG. 16, with the sapphire substrate removed, in accordance with an embodiment of the present invention.

### DETAILED DESCRIPTION

In the following description, reference is made to the accompanying drawings where, by way of illustration, specific embodiments of the invention are shown. It is to be understood that other embodiments may be used as structural and other changes may be made without departing from the scope of the present invention. Also, the various embodiments and aspects from each of the various embodiments may be used in any suitable combinations. Accordingly, the drawings and detailed description are to be regarded as illustrative in nature and not as restrictive.

Generally, embodiments of the present invention are directed to stacked host substrate for use in LED fabrication processes. The host substrate combines semiconductor materials and metals as a new conductive substrate for nitride based, thin-film semiconductor devices. Embodiments of the present invention include semiconductor materials for the cutting street areas, while the metals are inserted for mechanical support as well as a thermal and electrical conductor in the active regions. Several methods are described to create such a substrate structure according to embodiments of the present invention.

One example method includes etching a pattern of holes in a semiconductor layer, such as silicon layer, plating the silicon layer with a metal, such as copper, to fill the holes etched in the silicon layer; bonding the silicon layer to a gallium nitride (GaN) layer, the GaN layer attached to a sapphire substrate; and removing the sapphire substrate. Another example method includes etching a pattern of blind holes in a semiconductor, such as silicon, bonding the semiconductor to a GaN layer, the GaN layer attached to a sapphire substrate; thinning down the silicon layer to expose the patterned holes; plating the metal such as copper inside the patterned holes in the silicon; and removing the sapphire substrate.

According to embodiments of the present invention, the host substrate includes a combination of materials combined in way that produces an efficient, reliable light emitting device. Embodiments of the host substrate provide better mechanical support than pure copper, maintain the a high level of thermal and electrical conductivity, reduce stress caused by CTE mismatch problems, allows for easy cutting, and may be integrated with circuits. One embodiment of the present invention includes a host substrate comprising silicon and copper.

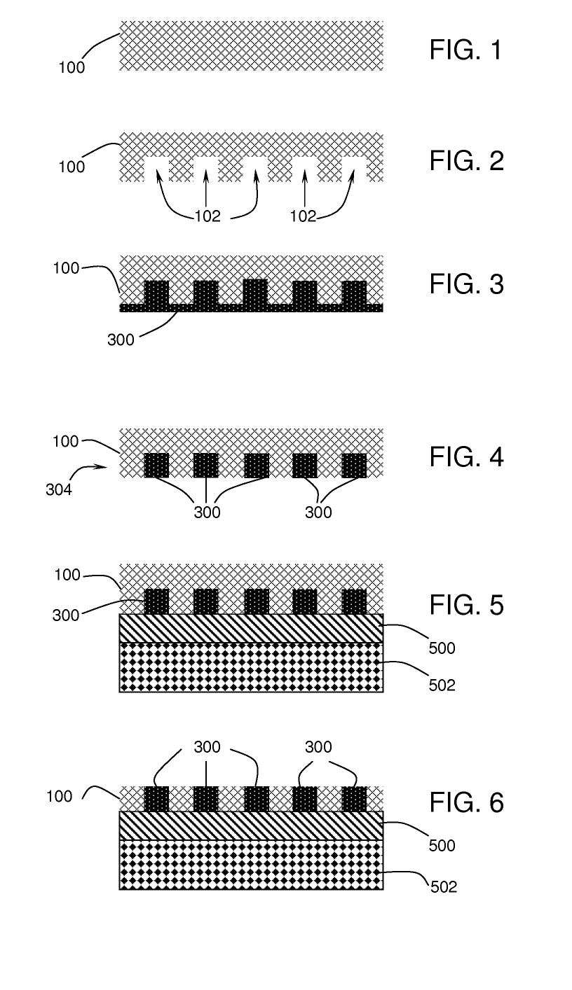

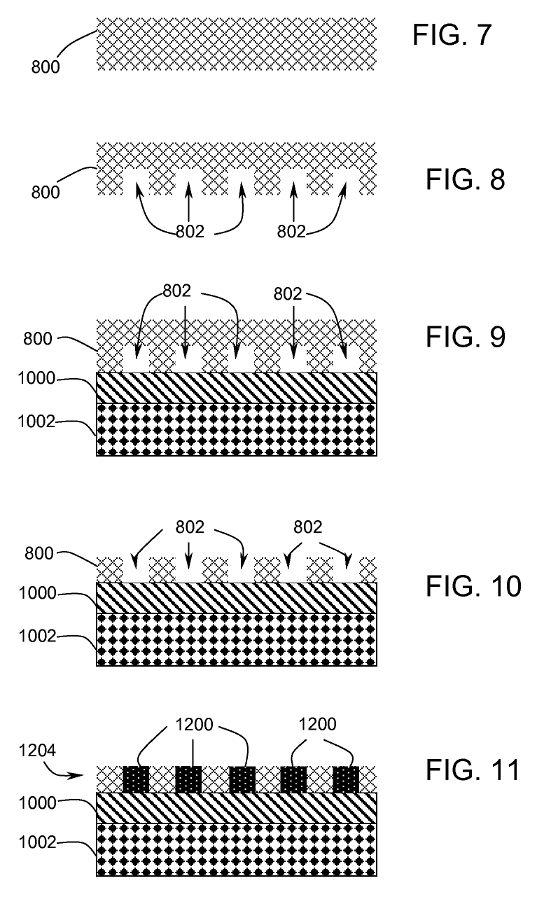

FIGS. 1 to 6 are cross sectional views illustrating the process flow of one example method of fabricating the host substrate and attaching it to the nitride layers. FIGS. 7 to 11 are cross sectional views illustrating the process flow of another example method of fabricating the host substrate and attaching it to the nitride layers. FIG. 13 is a plan view of the semiconductor structure shown in both FIG. 6 and FIG. 11.

Referring now to the figures, FIG. 1 is a partial cross sectional view of a layer of silicon (Si) 100. As shown in FIG. 2, the silicon is then patterned and a plurality of holes 102 are etched into the silicon 100 to a predetermined depth. Any suitable depth may be used. Any suitable pattern, size, and shape of the holes may be etched into the silicon. One example depth is greater than 5 um. Another example depth is approximately 100 um. Referring to FIG. 3, copper (Cu) plating 300 is then used to fill and cover the holes 102. Referring to FIG. 4, a polishing or mechanical planarization is used to remove the excess copper 300. Accordingly, a host substrate comprising silicon 100 and copper 300 is provided.

Referring to FIG. 5, the host substrate is bonded to one or more GaN layers 500 of a semiconductor structure. The one or more GaN layers 500 are formed on a sapphire substrate 502. Referring to FIG. 6, the silicon 100 is polished to expose the copper 300 in the host substrate. In the resulting semiconductor structure shown in FIG. 6, the copper 300 and silicon 100 have a parallel connection to a p-GaN layer of the one or more GaN layers 500. Because Cu has better conductivity, Cu and Si having a parallel connection to the p-GaN, the heat and the current will mostly pass through the copper 300, and therefore the host substrate may provide similar heat dissipation and electrical conductivity as a copper substrate.

Referring now to FIGS. 7 to 11, a semiconductor structure fabrication process using a host substrate is shown, according to a second embodiment of the present invention. FIG. 7 is a partial cross sectional view of a layer of silicon (Si) 800. Referring now to FIG. 8, the silicon is then patterned and a plurality of holes 802 are etched into the silicon 800 to a predetermined depth. Any suitable pattern and size and shape of holes may be etched into the silicon. One example depth is greater than 5 um. Another example depth is approximately 100 um. Referring to FIG. 9, the silicon layer 800 is bonded to one or more GaN layers 1000 of a semiconductor structure. The one or more GaN layers 1000 are formed on a sapphire substrate 1002. Referring to FIG. 10, the silicon 100 is polished to expose the holes that were etched into the silicon 800. Referring to FIG. 11, copper (Cu) 1200 plating is then used to fill and cover the holes 802. If necessary, a polishing or mechanical planarization process may be used to remove any excess copper 1200. Accordingly, a host substrate 1204 comprising silicon 100 and copper 300 is provided.

In the resulting semiconductor structure shown in FIG. 11, similar to the first embodiment of the fabrication process illustrated in FIGS. 1 to 6, the copper 1200 and silicon 800 have a parallel connection to a p-GaN layer of the one or more GaN layers 1000, and therefore, the semiconductor structure provides similar advantages.

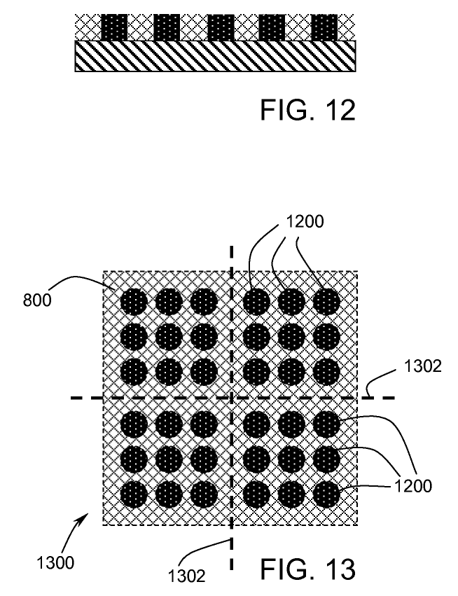

Referring now to FIG. 12, the sapphire substrate 1002 of the semiconductor structure shown in FIG. 11 has been removed.

Referring now to FIG. 13, a plan view of the semiconductor structure 1300 shown in FIGS. 6 and 11 is shown, in accordance with an embodiment of the present invention. The plan view of the semiconductor structure shows the silicon 800 and a pattern of copper 1200 filled into the silicon 800 layer. Dashed lines 1302 generally illustrate dicing streets in the semiconductor structure 1300. The dicing streets are located in the silicon portion of the semiconductor structure. Therefore, cutting of the semiconductor structure 1300 can be made by cutting through the silicon 800 portion of the semiconductor structure, and other circuit modules can be fabricated in the silicon areas and integrated with LEDs as a driver or to perform other functions.

One advantage of the second embodiment of the fabrication process, illustrated in FIGS. 7 to 11, and in other embodiments, is that the host substrate may be more easily bonded to the GaN layer because it is easier to bond one flat material to another flat material. However, both the first and second embodiment of the fabrication processes may be used, and both produce a resulting host substrate with improvements over the prior art.

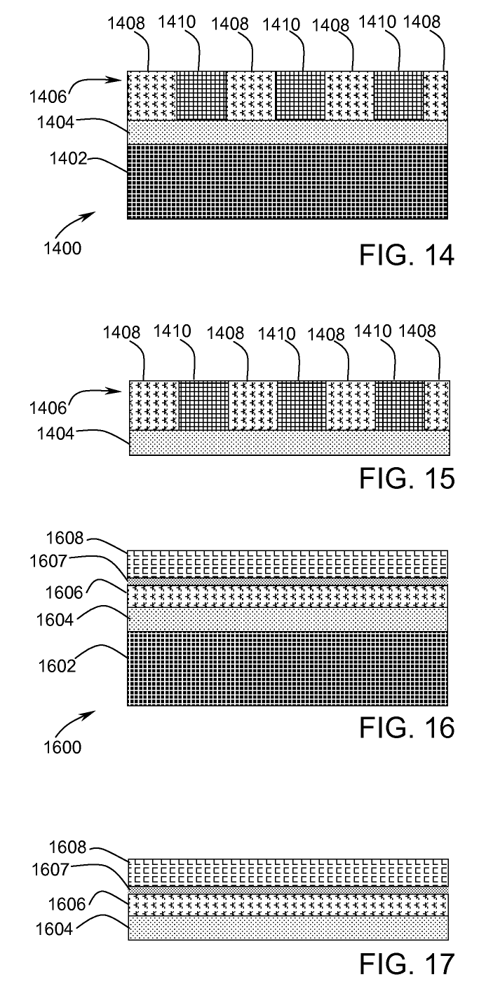

FIG. 14 is a partial cross sectional view of a semiconductor structure 1400, in accordance with an embodiment of the present invention. The semiconductor structure 1400 includes a sapphire substrate 1402, one or more GaN layers 1404, and a host substrate 1406 bonded to the one or more GaN layers 1404. The host substrate 1406 includes a combination of alternating copper (Cu) 1408 and nickel (Ni) 1410. The semiconductor structure shown in FIG. 14 is fabricated similar to either the process illustrated and described with reference to FIGS. 1 to 6 or the process illustrated and described with reference to FIGS. 7 to 11. However, in either process, a first lithography process is used to selectively plate the first metal, either copper or nickel, and then a second lithography process is used to selectively plate the second metal into the voids left by the first lithograph process, either copper or nickel, depending on which was used in the first lithograph process.

The host substrate 1406 relieves stress by separating the copper into different areas and inter-cross plating the copper with a second metal having lower thermal expansion. Therefore, there is less warping and expansion when compared to the use of a copper substrate. One example of inter-cross plating includes alternating strips of the copper and the second metal. Another example of inter-cross plating includes alternating sections of the copper and the second metal, the sections being any shape and size adjacent to each other on the surface of the one or more GaN layers 1404. Embodiments of the present invention may also include the host substrate 1406 having two or more different types of metal.

FIG. 15 is a partial cross sectional view of the semiconductor structure shown in FIG. 14, with the sapphire substrate removed, in accordance with an embodiment of the present invention.

FIG. 16 is a partial cross sectional view of a semiconductor structure, in accordance with an embodiment of the present invention. The semiconductor structure 1600 includes a sapphire substrate 1602, one or more GaN layers 1604 formed on the sapphire substrate 1602, a layer of copper 1606 plated to the one or more GaN layers 1604, a bonding metal 1607, and a layer of silicon 1608 bonded to the layer of copper 1606 with any suitable bonding metals 1607. A host substrate, therefore, is a stacked substrate comprising a metal stacked with a semiconductor. The illustrated embodiment includes the layer of copper 1606 and the layer of silicon 1608, and any necessary bonding metals 1607.

The host substrate and the semiconductor structure 1600 may be formed using any suitable lithography and bonding methods. According to one example process, less than 100 um of copper 1606 is electroplated on to the one or more GaN layer 1604. The silicon layer 1608 is bonded to copper layer 1606 by thermo compression, solder bonding, or eutectic bonding at a relatively high temperature, such as, for example, a temperature greater than or approximately equal to 200 degrees centigrade. Other bonding methods may also be used.

Embodiments of the of the host substrate shown in FIGS. 16 and 17 result in a semiconductor device with less warping and more convenient device fabrication. The host substrate also provides improved mechanical support and greater thermal and electrical conductivity when compared to silicon.

FIG. 17 is a partial cross sectional view of the semiconductor structure shown in FIG. 16, with the sapphire substrate removed, in accordance with an embodiment of the present invention.

Embodiments of the present invention provide a number of advantages over the prior art. According to one embodiment, the host substrate can be used to reduce the amount of stress when compared to a copper substrate because copper is applied to a smaller area. The thermal and electrical conductivity of the host substrate, according to embodiments of the present invention, may be comparable to copper by optimizing the designs. Additionally, integration with circuits is possible with embodiments of the present invention, because at least some areas of the host substrate are reserved for silicon, and other devices can be built upon the silicon.

While the invention has been particularly shown and described with reference to the illustrated embodiments, those skilled in the art will understand that changes in form and detail may be made without departing from the spirit and scope of the invention. For example, while certain etching patterns are illustrated and described, any other suitable etching patterns may be used, and those shown are provided for the purpose of illustration. Similarly, while certain materials are specified, other materials and metals having similar properties and providing a similar performance may also be used. For example, some suitable materials for use as the semiconductor layer may include Si, Ge, GaAs, III-V nitride, InP and ZnO. However, the embodiments of the present invention should therefore not be limited to these specified materials. Also, while a certain depth of holes has been indicated for the copper plating, other suitable depths may also be considered and used so as to avoid or reduce interconnection issues.

Accordingly, the above description is intended to provide example embodiments of the present invention, and the scope of the present invention is not to be limited by the specific examples provided.

1. A method of making a host substrate for nitride based thin-film semiconductor devices, the method comprising:
providing a semiconductor layer;
etching a pattern of holes in the semiconductor layer; plating the semiconductor layer with metal to fill the holes etched in the semiconductor layer; bonding the semiconductor layer to a gallium nitride (GaN) layer, the GaN layer attached to a sapphire substrate; and
removing the sapphire substrate.

2. The method of claim 1, wherein the semiconductor layer is silicon and the metal is copper.

3. The method of claim 1, wherein the depth of the holes etched in the semiconductor layer is greater than 10 um.

4. The method of claim 1, wherein the step of plating the semiconductor layer with metal to fill the holes etched in the semiconductor layer produces excess metal on the semiconductor layer, and the method of making a host substrate further comprises removing the excess metal using mechanical planarization.

5. The method of claim 1, wherein the step of plating the semiconductor layer with metal to fill the holes etched in the semiconductor layer produces excess metal on the semiconductor layer, and the method of making a host substrate further comprises removing the excess metal using chemical polishing.

6. The method of claim 1, wherein the plated semiconductor layer has a coefficient of thermal expansion (CTE) that is compatible with a CTE of the GaN layer.

7. The method of claim 1, wherein a plurality of dicing streets are formed in the semiconductor layer, wherein the plurality of dicing streets are configured to permit cutting through the semiconductor portion of the metal plated semiconductor layer, and wherein the method further comprises dicing the semiconductor structure along the plurality of dicing streets.

8. A method of making a host substrate for nitride based thin-film semiconductor devices, the method comprising:
providing a silicon layer;
etching a pattern of blind holes in a side of the silicon layer;
bonding the silicon layer to a gallium nitride (GaN) layer, the GaN layer attached to a sapphire substrate, wherein the side of the silicon layer having the pattern of holes is bonded to the GaN layer;
thinning the silicon layer to expose the pattern of holes in the silicon layer;
plating the silicon layer with copper to fill the holes etched in the silicon layer; and
removing the sapphire substrate.

9. The method of claim 8, wherein the depth of the holes etched in the silicon is greater than 5 um.

10. The method of claim 8, wherein the step of plating the silicon layer with copper to fill the holes etched in the silicon layer produces excess copper on the silicon layer, and the method of making a host substrate further comprises removing the excess copper using mechanical planarization.

11. The method of claim 8, wherein the step of plating the silicon layer with copper to fill the holes etched in the silicon layer produces excess copper on the silicon layer, and the method of making a host substrate further comprises removing the excess copper using chemical polishing.

12. The method of claim 8, wherein a plurality of dicing streets formed in the silicon layer, wherein the plurality of dicing streets are configured to permit cutting through the silicon portion copper pilated silicon layer, and wherein the method further comprises dicing the semiconductor structure along the plurality of dicing streets.

13. A nitride-based semiconductor structure comprising:
a host substrate; and
one or more nitride-based semiconductor layers bounded to the host substrate, wherein the host substrate includes a plurality of metal sections and defines a plurality of holes patterned in the host substrate, and wherein the plurality of metal sections include metal filled in the plurality of holes.

14. The nitride-based semiconductor structure of claim 13, wherein the host substrate includes Si, Ge, GaAs, III-V nitride, InP, or ZnO.

15. The nitride-based semiconductor structure of claim 13, further comprising a plurality of dicing streets formed in the host substrate, wherein the plurality of dicing streets are configured for dicing of the nitride-based semiconductor structure.

16. The nitride-based semiconductor structure of claim 15, wherein the plurality of holes are positioned such that the plurality of dicing streets are outside the holes.

17. The nitride-based semiconductor structure of claim 13, wherein the host substrate is a thermal conductor and an electrical conductor.

18. (canceled)

19. A nitride-based semiconductor structure having a host substrate, the nitride-based semiconductor structure comprising:
a sapphire substrate;
one or more gallium nitride (GaN) layers formed on the sapphire substrate;
a metal layer plated to the one or more GaN layers; and
a semiconductor layer bonded to the metal layer.

20. The thin-film nitride-based semiconductor structure of claim 19, wherein the metal layer is a layer of copper having a thickness of less than approximately 100 um, the layer of copper electroplated to the one or more GaN layer.

21. The thin-film nitride-based semiconductor structure of claim 19, wherein the semiconductor layer is a layer of silicon bonded to the layer of copper.

22. The thin-film nitride-based semiconductor structure of claim 19, wherein the layer of silicon is bonded to the layer of copper at a temperature greater than approximately 200 degrees centigrade.

23. The thin-film nitride-based semiconductor structure of claim 19, further comprising a plurality of dicing streets in the silicon layer, wherein the plurality of dicing streets are configured for dicing of the thin-film nitride-based semiconductor structure.

24. A nitride-based semiconductor structure having a host substrate, the nitride-based semiconductor structure comprising:
a sapphire substrate; and
one or more gallium nitride (GaN) layers formed on the sapphire substrate;
a metal layer plated to the one or more GaN layers, wherein the metal layer includes a combination of two different metals.

25. The thin-film nitride-based semiconductor structure of claim 24, wherein the metal layer includes copper and nickel inter-cross plated on the one or more GaN layers.

26. The thin-film nitride-based semiconductor structure of claim 24, wherein the sapphire substrate is removed.
